(19) United States
(12) Patent Application Publication
(10) Pub. No.: US 2021/0210118 A1
(43) Pub. Date: Jul. 8, 2021

(54) RECORDING LAYER, OPTICAL DATA RECORDING MEDIUM, AND SPUTTERING TARGET

(71) Applicant: Kabushiki Kaisha Kobe Seiko Sho (Kobe Steel, Ltd.), Kobe-shi (JP)

(72) Inventor: Yuki TAUCHI, Kobe-shi (JP)

(73) Assignee: Kabushiki Kaisha Kobe Seiko Sho (Kobe Steel, Ltd.), Kobe-shi (JP)

(21) Appl. No.: 17/055,343

(22) PCT Filed: May 22, 2019
(86) PCT No.: PCT/JP2019/020323

§ 371 Date: Nov. 13, 2020

(30) Foreign Application Priority Data
Jun. 7, 2018 (JP) 2018-109216
Dec. 28, 2018 (JP) 2018-248558

(51) Int. Cl. G11B 7/24067; C23C 14/34; C23C 14/08; G11B 7/127; G11B 7/26

(52) U.S. Cl. CPC G11B 7/24067; C23C 14/3407; G11B 7/266; C23C 14/085; G11B 7/127; C23C 14/083

(57) ABSTRACT

A recording layer for an optical data recording medium is described. Recording is performed by irradiating the recording layer with a laser beam. The recording layer contains a W oxide, an Fe oxide, and at least one of a Ta oxide and a Nb oxide. The recording layer contains 10-60 atomic % of Fe and a total of 3-50 atomic % of Ta and Nb relative to the total metal atoms therein.

### TECHNICAL FIELD

The present invention relates to a recording layer, an optical data recording medium, and a sputtering target.

### BACKGROUND ART

The optical data recording medium typified by an optical disc such as, for example, a compact disc (CD) and a digital versatile disc (DVD) is classified into three types: read-only, write-once, and rewritable. Of these, a known recording method of the write-once optical disc includes, for example, a method using phase transition of a material of a recording layer, a method using a reaction of a material of a recording layer, a method using decomposition of a material of a recording layer, and a method using holes formed in a recording layer.

Among them, as the method using decomposition of the material of the recording layer, there have been provided a method using Mn oxide in Japanese Unexamined Patent Application Publication No. 2012-139876, a method using Pd oxide in Japanese Unexamined Patent Application Publication No. 2011-62981, and a method using W—Fe oxide in Japanese Unexamined Patent Application Publication No. 2014-26704.

### CITATION LIST

### Patent Literature

Patent Literature 1: Japanese Unexamined Patent Application Publication No. 2012-139876

Patent Literature 2: Japanese Unexamined Patent Application Publication No. 2011-62981

Patent Literature 3: Japanese Unexamined Patent Application Publication No. 2014-26704

### SUMMARY OF INVENTION

### Technical Problem

Major demand characteristics required for the optical data recording medium include a sufficiently high reflectivity, a sufficiently high modulation degree (a large change in reflectivity due to recording), a sufficiently high recording sensitivity (acceptable recordability by a laser with a practical output level), a sufficiently large power margin, and a sufficiently small jitter (high signal accuracy).

In the configurations described in the patent application publications, since such demand characteristics are difficult to be fully satisfied by a single-layer recording layer, the optical data recording medium is formed while a function layer is stacked on the recording layer to supplement characteristics that the recording layer lacks in. Specifically, it is necessary to stack a reflective layer on a back (opposite to a laser irradiation surface) of the recording layer because sufficient reflectivity is not given only by the recording layer, or stack a dielectric layer because a sufficient modulation degree is not given only by the recording layer. The configurations of the above-described publications therefore each have a large number of layers, leading to a difficulty in improvement in productivity of the optical data recording medium.

Some optical recording medium has a plurality of recording layers. Such a multilayer optical recording medium requires a high transmissivity of each recording layer. In the configurations of the above-described publications with a large number of layers, therefore, transmissivity of the recording layer is disadvantageously difficult to be increased.

In light of the above-described circumstances, an object of the invention is to provide a recording layer having acceptably good characteristics by itself, an optical data recording medium having good productivity, and a sputtering target allowing formation of a recording layer having acceptably good characteristics by itself.

### Solution to Problem

To achieve the object, a recording layer according to one aspect of the invention is for an optical data recording medium in which recording is performed by laser beam irradiation. The recording layer contains W oxide, Fe oxide, and at least one of Ta oxide and Nb oxide, where 10 to 60 atomic % Fe and 3 to 50 atomic % Ta and Nb in total are contained in all metal atoms.

The recording layer can include W oxide, Fe oxide, and at least one of Ta oxide and Nb oxide to reduce an extinction coefficient while increasing refractivity, and make other characteristics to be acceptably good. Specifically, the Fe content in all metal atoms can be adjusted to be within the above range to reduce energy required for pyrolysis of the material of the recording layer while securing a relatively high transmissivity. The total content of Ta and Nb in all metal atoms can be adjusted to be within the above range to allow the recording layer to have an acceptably good modulation degree, jitter value, and power margin. As a result, the recording layer achieves acceptably good characteristics by itself.

The recording layer preferably further contains at least one of Mn oxide, Cu oxide, Zn oxide, Ag oxide, and Al oxide. In this way, the recording layer can further contain at least one of Mn oxide, Cu oxide, Zn oxide, Ag oxide, and Al oxide to adjust recording sensitivity, transmissivity, and reflectivity of the recording layer.

The recording layer preferably has an average thickness of 15 to 60 nm. The average thickness within the above range makes it possible to further improve the reflectivity, the modulation degree, and the transmissivity of the recording layer.

An optical data recording medium according to another aspect of the invention includes the above-described recording layer. The optical data recording medium has good productivity because it has smaller number of layers due to the recording layer having acceptably good characteristics by itself.

The optical data recording medium preferably further has a protective layer that is stacked on at least one surface of the recording layer, contains a metal oxide as a main composition, and has an average thickness of 5 to 50 nm. As described above, the optical data recording medium further has the protective layer that is stacked on at least one surface of the recording layer, contains a metal oxide as the main composition, and has an average thickness within the above range, making it possible to improve environmental tolerance of a recorded signal.

A sputtering target according to another aspect of the invention is to form by sputtering a recording layer for an optical data recording medium in which recording is performed by laser beam irradiation. The sputtering target contains W, Fe, and at least one of Ta and Nb, where 10 to 60 atomic % Fe and 3 to 50 atomic % Ta and Nb in total are contained in all metal atoms.

The sputtering target contains W, Fe, and at least one of Ta and Nb and has the Fe content and the total content of Ta and Nb in all metal atoms that are adjusted within the above-described respective ranges, making it possible to form a recording layer having acceptably good characteristics by itself.

It is noted that “main composition” means a composition having the largest mass content.

### Advantageous Effects of Invention

As described above, the recording layer according to the invention and the recording layer formed using the sputtering target according to the invention each have acceptably good characteristics by itself. In addition, the optical data recording medium according to the invention has good productivity.

### BRIEF DESCRIPTION OF DRAWING

FIG. 1 is a schematic sectional diagram illustrating a configuration of an optical data recording medium of one embodiment of the invention.

### DESCRIPTION OF EMBODIMENTS

Some embodiments of the invention will now be described in detail with reference to the drawing as necessary.

Optical data Recording Medium

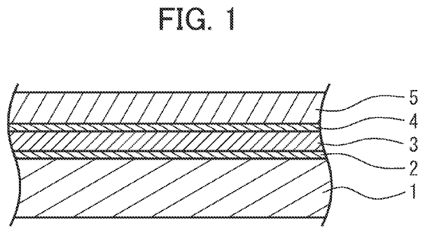

FIG. 1 illustrates a layer structure of an optical disc of one embodiment of an optical data recording medium according to the invention. The optical data recording medium includes a substrate 1, a back protective layer 2 stacked on a surface of the substrate 1, a recording layer 3 stacked on a surface of the back protective layer 2, a surface protective layer 4 stacked on a surface of the recording layer 3, and a light transmitting layer 5 stacked on a surface of the surface protective layer 4. In the optical data recording medium, the recording layer 3 is one embodiment of the recording layer according to the invention in itself.

### Substrate

The substrate 1 is a disc-like component supporting the recording layer 3. Examples of a usable material of the substrate 1 include polycarbonate, norbornene resin, cyclic olefin copolymer, and amorphous polyolefin. The average thickness of the substrate 1 can be adjusted to 0.5 mm to 1.2 mm, for example.

### Back Protective Layer

The back protective layer 2 is provided to improve environmental resistance of a signal recorded on the optical data recording medium. That is, the back protective layer 2 is provided to prevent oxygen or water from infiltrating into the recording layer 3 through the substrate 1, and thus degenerating a material of the recording layer 3 and disabling reading of the recorded information.

The back protective layer 2 contains a metal oxide as a main composition. Preferred examples of the main composition of the back protective layer 2 include Zn oxide, In oxide, Sn oxide, Si oxide, Al oxide, Zr oxide, and Ga oxide. A mixture of such oxides may also be used.

The lower limit of average thickness of the back protective layer 2 is preferably 5 nm, more preferably 10 nm. The upper limit of average thickness of the back protective layer 2 is preferably 50 nm, more preferably 20 nm. If the average thickness of the back protective layer 2 is less than the lower limit, the back protective layer 2 has insufficient barrier performance, and thus a recorded signal may not be prevented from being lost due to degeneration of the recording layer 3. Conversely, if the average thickness of the back protective layer 2 exceeds the upper limit, reflectivity of the recording layer 3 may be reduced due to optical interference, or productivity may be unnecessarily reduced.

### Recording Layer

The recording layer 3 is formed of a material containing W oxide (tungsten oxide), Fe oxide (iron oxide), and at least one of Ta oxide (tantalum oxide) and Nb oxide (niobium oxide). Specifically, the Fe oxide in the recording layer 3 contains a peroxide that is decomposed by heat of laser beam during recording to form a recorded mark.

The recording layer 3 can contain W oxide, Fe oxide, and at least one of Ta oxide and Nb oxide to reduce an extinction coefficient (absorption coefficient) while maintaining a high refractivity, and thus has high reflectivity and high transmittance together. Since the recording layer 3 formed of such a material can have a high modulation degree, a high-quality recorded signal can be given.

The lower limit of the total content of W, Fe, Ta, and Nb in all metal atoms in the recording layer 3 is preferably 70 atomic %, more preferably 80 atomic %. The upper limit of the total content of W, Fe, Ta, and Nb in all metal atoms in the recording layer 3 is not limited, but may be 100 atomic %. If the total content of W, Fe, Ta, and Nb in all metal atoms in the recording layer 3 is less than the lower limit, the above-described desired characteristics may not be exhibited.

### W

The lower limit of the content of W in all metal atoms in the recording layer 3 is preferably 20 atomic %, more preferably 30 atomic %. The upper limit of the content of W in all metal atoms in the recording layer 3 is preferably 80 atomic %, more preferably 70 atomic %. The content of W in all metal atoms in the recording layer 3 can be adjusted to be within the above range so that the recording layer 3 has required characteristics.

### Fe

The lower limit of the content of Fe in all metal atoms in the recording layer 3 is 10 atomic %, preferably 15 atomic %. The upper limit of the content of Fe in all metal atoms in the recording layer 3 is 60 atomic %, preferably 50 atomic %. The content of Fe in all metal atoms in the recording layer 3 of less than the lower limit may lead to excessively large laser power required for recording. Conversely, the content of Fe in all metal atoms in the recording layer 3 of more than the upper limit may lead to insufficient transmissivity.

### Ta, Nb

The lower limit of the total content of Ta and Nb in all metal atoms in the recording layer 3 is 3 atomic %, preferably 10 atomic %. The upper limit of the total content of Ta and Nb in all metal atoms in the recording layer 3 is 50 atomic %, preferably 35 atomic %. If the total content of Ta and Nb in all metal atoms in the recording layer 3 is less than the lower limit, the modulation degree of the recording layer 3 is small, leading to a possibility of an excessive jitter value or an insufficient power margin. Conversely, if the total content of Ta and Nb in all metal atoms in the recording layer 3 exceeds the upper limit, excessively large laser power may be necessary for recording, or manufacturing cost of the recording layer 3 may unnecessarily increase.

### Other Metals

The recording layer 3 may further contain one or more of Mn oxide, Cu oxide, Zn oxide, Ag oxide, and Al oxide in addition to W oxide, Fe oxide, and at least one of Ta oxide and Nb oxide. The recording layer 3 can further contain Mn oxide, Cu oxide, Zn oxide, Ag oxide, and/or Al oxide to adjust characteristics of the recording layer 3, such as recording sensitivity, transmissivity, and reflectivity. For example, the recording layer 3 can contain at least one of Mn oxide and Cu oxide to increase absorptivity of the recording layer 3. The recording layer 3 can contain at least one of Zn oxide, Ag oxide, and Al oxide to reduce absorptivity of the recording layer 3.

The lower limit of average thickness of the recording layer 3 is preferably 15 nm, more preferably 25 nm. The upper limit of average thickness of the recording layer 3 is preferably 60 nm, more preferably 50 nm, and most preferably 40 nm. The average thickness of the recording layer 3 of less than the lower limit may lead to insufficient reflectivity or an insufficient modulation degree. Conversely, the average thickness of the recording layer 3 more than the upper limit may lead to insufficient transmissivity.

### Surface Protective Layer

The surface protective layer 4 can be formed as a thin layer like the back protective layer 2.

### Light Transmitting Layer

A usable material of the light transmitting layer 5 has a high transmissivity and low absorptivity of laser beam for recording and reproduction. Specifically, the light transmitting layer 5 can be formed of, for example, polycarbonate or ultraviolet curable resin. The average thickness of the light transmitting layer 5 can be adjusted to 0.1 mm to 1.2 m, for example.

Method for Manufacturing Optical data Recording Medium

The optical data recording medium can be manufactured by a method including: a back protective layer formation step, or a step of forming the back protective layer 2 on the surface of the substrate 1; a recording layer formation step, or a step of forming the recording layer 3 on the surface of the back protective layer 2; a surface protective layer formation step, or a step of forming the surface protective layer 4 on the surface of the recording layer 3; and a light transmitting layer stacking step, or a step of stacking the light transmitting layer 5 on the surface of the surface protective layer 4.

### Back Protective Layer Formation Step

In the back protective layer formation step, the back protective layer 2 is formed by sputtering in an atmosphere gas containing oxygen. Examples of a usable sputtering target include a sintered body of one or more of Zn, In, Sn, Si, Al, Zr, and Ga. Different types of sputtering targets may be used together. Examples of a usable atmosphere gas include a mixed gas of an inert gas such as argon and oxygen. A volume ratio of the inert gas and oxygen in the atmosphere gas can be adjusted to approximately 1:1.

### Recording Layer Formation Step

In the recording layer formation step, the recording layer 3 is formed by sputtering using a sputtering target according to another embodiment of the invention.

### Sputtering Target

The sputtering target contains W, Fe, and at least one of Ta and Nb. W, Fe, Ta, and Nb may each be contained in a form of pure metal, alloy, or metal oxide, for example. The sputtering target may be a sintered body of a powder material mixture.

The respective contents of W, Fe, Ta, and Nb in all metal atoms in the sputtering target are set to be equal to the respective contents of W, Fe, Ta, and Nb in all metal atoms in the recording layer 3 to be formed.

The sputtering target can contain one or more of metals of Mn, Cu, Zn, Ag, and Al to form Mn oxide, Cu oxide, Zn oxide, Ag oxide, and/or Al oxide in the recording layer 3 to be formed. The respective contents of Mn, Cu, Zn, Ag, and Al in all metal atoms in the sputtering target are set to be equal to the respective contents of Cu, Zn, Ag, and Al in all metal atoms in the recording layer 3 to be formed.

The sputtering is performed in an atmosphere gas containing an inert gas and oxygen. Examples of a usable atmosphere gas include argon. A volume ratio of the inert gas and oxygen in the atmosphere gas can be adjusted to approximately 1:1.

### Surface Protective Layer Formation Step

In the surface protective layer formation step, the surface protective layer 4 is formed by sputtering as in the back protective layer formation step.

### Light Transmitting Layer Stacking Step

In the light transmitting layer stacking step, the light transmitting layer 5 is stacked on the surface protective layer 4 by applying a resin composition to the surface of the surface protective layer 4 and curing the resin composition or by thermocompression bonding of a thermoplastic resin composition to the surface.

### Advantages

The recording layer 3 of the optical data recording medium can contain W oxide, Fe oxide, and at least one of Ta oxide and Nb oxide to reduce an extinction coefficient while increasing refractivity and make other characteristics to be acceptably good. The recording layer 3 therefore can have acceptably good characteristics by itself. Consequently, the optical data recording medium has a relatively small number of layers and is thus high in productivity.

### Other Embodiments

The above-described embodiment is not intended to limit the configuration of the invention. The above embodiment therefore should be construed such that a component of each part in the embodiment can be omitted, replaced, or added based on the description and technical knowledge, all of which are covered by the scope of the invention.

In the optical data recording medium of the invention, each layer other than the recording layer may have any optional configuration.

The recording layer and the optical data recording medium of the invention may be manufactured not only by the above-described manufacturing method but also by another method.

The recording layer of the invention may be formed using the sputtering target containing one or two of metals of W, Fe, Ta, and Nb and a sputtering target containing another metal together.

### Example

Although the invention is now described in detail according to Example, the invention is not limitedly interpreted based on the description of the Example.

### Trial Samples

A polycarbonate substrate 12 cm in diameter (1.1 mm in thickness, 0.45 μm in track pitch, and 25 nm in trench depth) was used as a substrate, a back protective layer 14 nm in average thickness, a recording layer 32 nm in average thickness, and a surface protective layer 14 nm in average thickness were stacked in this order by sputtering, and an ultraviolet curable resin was applied by spin coating and cured by ultraviolet rays to form a light transmitting layer 0.1 mm in average thickness, thereby trial samples 1 to 16 of an optical disc (optical data recording medium) were produced.

In the trial samples 1 to 3 and 5 to 16, two or more materials selected from tungsten, iron (III) oxide (Fe₂O₃), zinc, tantalum, niobium, manganese, and molybdenum were used together for a sputtering target to form the recording layer. Only in the trial sample 4, a sintered body of a mixture of tungsten powder, iron (III) oxide powder, tantalum powder, and manganese powder was used as the sputtering target. A 1:1 mixture of argon and oxygen was supplied at a pressure of 0.26 Pa as an atmosphere gas during sputtering.

A sintered body of a mixture of tin powder, zinc powder, and zirconium powder was used as the sputtering target to form the back protective layer and the surface protective layer. A 1:1 mixture of argon and oxygen was supplied at a pressure of 0.26 Pa as an atmosphere gas during sputtering.

To accurately measure performance of the recording layer, respective test specimens were produced on glass substrates by stacking the back protective layers, the recoding layers, and the surface protective layers, which are the same as those of the trial samples 1 to 16, respectively, by sputtering under the same condition.

Compositions of the recoding layers of the optical-disc trial samples 1 to 16 produced in this way were determined by fluorescent X-ray analysis.

### Evaluation

Characteristics of the optical-disc trial samples 1 to 16 were evaluated using an optical disc evaluation apparatus “ODU-1000” from Pulstec Industrial Co., Ltd. A random signal of the Blu-ray disc standard was recorded with a central wavelength of a recording laser of 405 nm, a lens having an aperture factor (NA) of 0.85, and linear velocity of 4.92 m/s. Reflectivity was obtained from intensity of return light of the laser beam. A jitter value and a modulation degree were measured using a combination of the above optical disc evaluation apparatus, a time interval analyzer “TA-810” from Tektronix, Inc., and a digital oscilloscope “DL1640” from Yokogawa Electric Corporation. A power margin was standardized with the recording power at which the jitter value was minimized, and a ratio of a recording power range was calculated so as to secure a jitter value of 8.5% or lower in a plus-and-minus direction. For the reflectivity, a reflectivity value at a wavelength of 405 nm was measured with a test specimen including a film formed on a glass substrate using a spectrophotometer “V-570” from JASCO Corporation.

Table 1 collectively shows a composition of the recording layer, reflectivity, absorptivity, a jitter value, a modulation degree, and a power margin of each of the optical-disc trial samples 1 to 16. In the table, “-” in the composition column means “uncontained”. In the table, “-” in some measured values indicate unsuccessful information recording due to insufficient recording sensitivity.

TABLE 1

| | Recording layer | | | | | | | | | Minimum | Modulation | Power |
|---|---|---|---|---|---|---|---|---|---|---|---|---|
| | composition [atomic %] | | | | | | | Reflectance | Absorptivity | jitter | degree | margin |
| | W | Fe | Zn | Ta | Nb | Mn | Mo | [%] | [%] | [%] | [%] | [%] |
| Trial sample 1 | 60 | 26 | — | 14 | — | — | — | 30.8 | 6.6 | 5.4 | 54 | 34 |
| Trial sample 2 | 39 | 24 | — | 37 | — | — | — | 30.9 | 4.6 | 6.2 | 56 | 28 |
| Trial sample 3 | 51 | 23 | — | 26 | — | — | — | 30.8 | 4.6 | 5.6 | 62 | 31 |
| Trial sample 4 | 50 | 35 | — | 6 | — | 10 | — | 29.8 | 10.7 | 5.5 | 48 | 41 |
| Trial sample 5 | 65 | 31 | — | 4 | — | — | — | 31.0 | 7.8 | 5.4 | 46 | 34 |
| Trial sample 6 | 31 | 54 | — | 15 | — | — | — | 32.3 | 14.1 | 6.0 | 61 | 33 |
| Trial sample 7 | 46 | 35 | — | 2 | 9 | 8 | — | 30.6 | 9.6 | 5.0 | 57 | 39 |
| Trial sample 8 | 40 | 32 | — | 3 | 16 | 9 | — | 30.3 | 9.1 | 4.8 | 62 | 36 |
| Trial sample 9 | 34 | 29 | — | 3 | 28 | 6 | — | 30.6 | 7.6 | 4.8 | 64 | 34 |
| Trial sample 10 | 43 | 31 | — | — | 26 | — | — | 32.0 | 6.6 | 4.9 | 54 | 27 |
| Trial sample 11 | 50 | 33 | — | — | 17 | — | — | 30.8 | 7.5 | 4.7 | 53 | 32 |
| Trial sample 12 | 60 | 25 | — | — | — | — | 15 | 31.9 | 7.7 | 6.0 | 33 | 32 |
| Trial sample 13 | 31 | — | 39 | — | — | 30 | — | 26.1 | 18.8 | 6.6 | 59 | 43 |
| Trial sample 14 | 73 | 27 | — | — | — | — | — | 30.2 | 8.2 | 7.0 | 54 | 23 |
| Trial sample 15 | 81 | 6 | — | 13 | — | — | — | 29.7 | 1.3 | — | — | — |
| Trial sample 16 | 4 | 18 | — | 78 | — | — | — | 28.5 | 2.1 | — | — | — |

For respective characteristics of the optical disc, reflectivity of 0.29% or more, absorptivity of 3.0% to 15%, a jitter value of 6.5% or less, a modulation degree of 45% or more, and a power margin of 25% or more can each be considered to be excellent.

As shown in Table 1, the optical-disc trial samples 1 to 11, in each of which the recording layer contains W oxide, Fe oxide, and at least one of Ta oxide and Nb oxide, a certain amount of Fe in all metal atoms, and a certain amount of Ta. and Nb in total, are excellent in reflectivity, absorptivity, jitter value, modulation degree, and power margin, and thus probably need not complement a function by adding a layer other than the recording layer and the protective layer.

### INDUSTRIAL APPLICABILITY

The invention can be preferably used for optical discs.

### LIST OF REFERENCE SIGNS

1 Substrate
2 Back protective layer
3 Recording layer
4 Surface protective layer
5 Light transmitting layer

1. A recording layer for an optical data recording medium in which recording is performed by laser beam irradiation, the recording layer comprising:
W oxide;
Fe oxide; and
at least one selected from the group consisting of Ta oxide and Nb oxide,
wherein the recording layer comprises 10 to 60 atomic % Fe and 3 to 50 atomic % of the total of Ta and Nb, each atomic percentage relative to a total of all metal atoms in the recording layer.

2. The recording layer of claim 1, further comprising at least one selected from the group consisting of Mn oxide, Cu oxide, Zn oxide, Ag oxide, and Al oxide.

3. The recording layer of claim 1, wherein the recording layer has an average thickness of 15 nm to 60 nm.

4. The recording layer of claim 2, wherein the recording layer has an average thickness of 15 nm to 60 nm.

5. An optical data recording medium, comprising the recording layer of claim 1.

6. The optical data recording medium of claim 5, further comprising a protective layer stacked on at least one surface of the recording layer,
wherein the protective layer comprises a metal oxide as a main composition and
wherein the protective layer has an average thickness of 5 nm to 50 nm.

7. A sputtering target to form a recording layer for an optical data recording medium by sputtering, in which recording of the recording layer is performed by laser beam irradiation, the sputtering target comprising:
W;
Fe; and
at least one selected from the group consisting of Ta and Nb,
wherein the sputtering target comprises 10 to 60 atomic % Fe, and 3 to 50 atomic % of the total of Ta and Nb, each atomic percentage relative to a total of all metal atoms in the sputtering target.
